(19) United States
(12) Patent Application Publication
(10) Pub. No.: US 2020/0251852 A1
(43) Pub. Date: Aug. 6, 2020

(54) CONNECTOR ELEMENT FOR AN ELECTRONIC COMPONENT, ELECTRONIC COMPONENT AND METHOD FOR ASSEMBLING AN ELECTRONIC COMPONENT

(71) Applicant: VITESCO TECHNOLOGIES GMBH, HANNOVER (DE)

(72) Inventor: DORIN DIACONU, MUENCHEN (DE)

(21) Appl. No.: 16/652,235

(22) PCT Filed: Oct. 4, 2018
(86) PCT No.: PCT/EP2018/077056

§ 371 Date: Mar. 30, 2020

(30) Foreign Application Priority Data
Oct. 13, 2017 (EP) 17465562

(51) Int. Cl. H01R 13/52; H01R 12/72; H05K 5/00

(52) U.S. Cl. CPC H01R 13/5213; H05K 5/0052; H01R 13/5202; H01R 12/724

(57) ABSTRACT

A connector element for an electronic component includes a connecting region for connecting a circuit board to the connector element and a connector for connecting the connector element to another component. The connector element includes a sealing area intended to be brought in contact with a corresponding mating area of a housing. The sealing area has a narrow groove intended to be filled with a sealing material in a dispensing process. The narrow groove includes a dispensing starting region and the dispensing starting region has a width larger than the width of the narrow groove and a conically shaped side wall, in which the tip of the conus points towards the depth of the narrow groove. An electronic component and a method for assembling the electronic component are also provided.

The present invention relates to a connector element for an electronic component. It further relates to an electronic component and to a method for assembling an electronic component.

An electronic component, for example a control unit in a vehicle, is assembled of several parts. Typically, the electronic component has a circuit board with a control circuit, some kind of connector element for providing a power supply and a data connection for the electronic component and a housing which protects the control circuit. The housing may be formed of a metal or a plastic material and is typically in some way connected to the connector element.

In a new type of housing, where the housing is connected to the connector element by a sealing material which is dispensed in a sealing area, the assembly of the electronic component was problematic. The sealing material was to be dispensed after the circuit board was connected to the connector element. The circuit board, however, protrudes widely from the connector element, making it necessary to use a relatively long needle for the dispensing process. A long needle, however, is difficult to handle in an automated process.

It is an object of the present invention, to provide a connector element, where the dispensing process can be performed automatically and securely in a short time.

It is a further object of the present invention, to provide an electronic component with such a connector element and an economic method for assembling the electronic component.

These objects are achieved by means of the connector element, the electronic component and the method according to the independent claims.

Advantageous embodiments and developments are specified in the dependent claims, the following description and the drawings.

According to an aspect of the invention, a connector element for an electronic component is provided, comprising a connecting region for connecting a circuit board to the connector element. The connector element further comprises a connector for connecting the connector element to another component, wherein the other component is a mating connector in one embodiment. The connector element comprises a sealing area intended to be brought in contact with a corresponding mating area of the housing, wherein the sealing area comprises a—preferably narrow—groove intended to be filled with the sealing material in the dispensing processes. The groove comprises a dispensing starting region. The dispensing starting region has a width larger than the width of the groove and a conically shaped side wall. The tip of the conus points towards the depth of the groove. To put it differently, the conically shaped side wall tapers in direction towards a bottom of the groove.

According to the invention, the connector element connects the circuit board and its electronic circuit to another component, for example to a data cable or to a different electronic component.

The connector element has the advantage, that a dispensing needle can be positioned easily, because the dispensing starting region serves to centre the needle due to its conically side wall. The conically shaped side wall makes a funnel-shaped section of the groove and thus helps to insert the dispensing needle into the narrow groove. As a relatively long needle is used in the dispensing process, a slight bend of the needle would cause the needle tip to miss the narrow groove. However, it is an important requirement for an automated dispensing process to ensure that the needle tip is securely inside the narrow groove before the dispensing process is started.

Typically, it is not desirable to simply make the groove wider in order to solve problems with the insertion of the needle into the groove. Firstly, this would require a larger amount of sealing material, secondly, a wider groove would require more space on the connector element which is generally undesirable.

By providing a dispensing starting region with the conically shaped side wall as part of the narrow groove, the insertion of the needle into the groove is facilitated. This makes it possible to use an automated dispensing process.

According to an embodiment, the groove follows an outline of the connector of the connector element. For Example, the groove extends completely circumferentially around the connector, in particular in top view along a connection direction of the connector. The connection direction is in particular the direction in which the mating connector is shiftable into the connector. In one development, the groove has four sections forming a rectangular shape, in particular in top view along the connection direction. A rectangular shape in the present context includes a basically rectangular shape having rounded edges. The dispensing starting region with the conically shaped side wall may be particularly advantageous for dispensing into such circumferentially closed groove shapes.

In one embodiment, the dispensing starting region is comprised by one of the four sections at a distance from the edges of the rectangular shape. In this way, tolerance compensation of the dispensing needle during the start of the dispensing process may be particularly easy.

According to an embodiment of the invention, the conically shaped side wall is arranged on the inner section of the groove, whereas the outer section of the groove is evenly formed both in the dispensing starting region and outside.

According to this embodiment, the dispensing starting region is not visible from the outside of the connector element, which means that the groove is not widened towards the outside to form the dispensing starting region. In fact, the groove is only widened towards the inside of the connector element in order to form the dispensing starting region.

This has the advantage that the outside of the connector element does not need to be changed but can be formed evenly.

According to an embodiment, the sealing material is an adhesive. According to this embodiment, the housing may be connected to the connector element via the adhesive, optionally in combination with embedded clips (snappers).

According to an embodiment, the connector element is made of a plastic material by injection molding. Preferably, the connector element has a plastic base body which is a one-pieced—in particular injection molded—part. For example, the connector element consists of the base body and a multitude of electrically conductive—in particular metallic—connection elements.

This has the advantage, that the connector element can be formed very cost-efficient.

According to an aspect of the invention, the electronic component is provided comprising at least one circuit board, a housing arranged around the circuit board and the described connector element.

The circuit board may protrude from the connector element with a protruding distance D with D>5*b or even D>10*b, wherein b is the width of the groove.

According to this embodiment, the protruding distance D is comparatively large. This makes the dispensing process more difficult, because a long needle has to be used. However, the dispensing starting region provides the possibility to centre the needle securely in the narrow groove for an automated dispensing process.

According to an embodiment, the electronic component is a control unit of a selective catalytic reduction system (SCR) of a vehicle.

According to an aspect of the invention, a method for assembling the electronic component is provided, wherein the method comprises connecting the circuit board to the connecting region of the connector element and dispensing sealing material in the narrow groove starting in the dispensing starting region, the sealing material being dispensed by needle being positioned essentially parallel to the plane of the circuit board. The method further comprises arranging a housing around the circuit board, a mating region of the housing contacting the sealing region.

Further advantages, advantageous embodiment and developments of the connector elements, the electronic component and the method for assembling the electronic component will become apparent from the exemplary embodiments which are described below in association with the schematic figures.

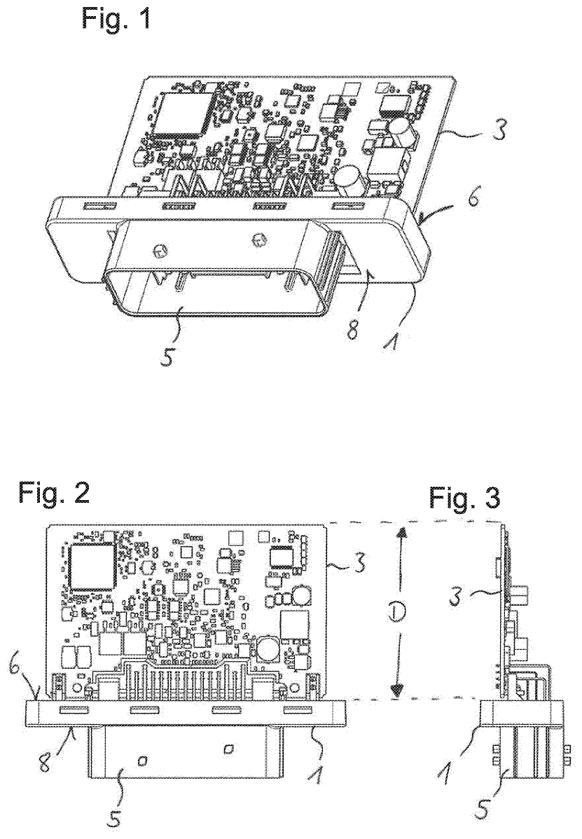

FIG. 1 shows a perspective view of the connector element with a circuit board according to an embodiment of the invention,

FIG. 2 shows a side view of the connector element according to FIG. 1,

FIG. 3 shows a second side view of the connector element according to FIG. 1,

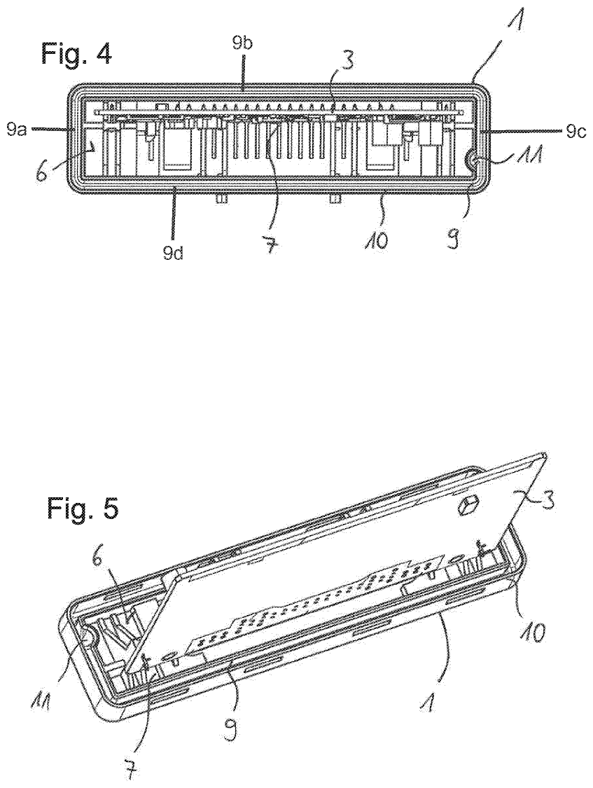

FIG. 4 shows a plan view of the connector element with a circuit board according to FIG. 1 and

FIG. 5 shows a second perspective view of the connector element according to FIG. 1.

FIG. 1 shows a connector element 1 which is made of plastic material in a injection molding process. The connector element 1 serves to connect an electronic circuit on the circuit board 3 to another electronic component, which is not shown in the figures, for example to a data cable and to a power supply.

The connector element 1 has a connector 5 for connecting the connector element 1 to the other component. The circuit board 3 is arranged on a first side 6 of the connector element 1 in a connecting region which is not shown in FIG. 1. The connector 5 is arranged and a second side 8 of the connector element 1 opposite the first side 6.

FIGS. 2 and 3 show side views of the connector element 1. From these views it can be seen, that the circuit board 3 protrudes from the connector element 1 by the protruding distance D.

FIGS. 4 and 5 show the connector element 1 from the first side 6. On the first side 6 there is arranged the connecting region 7, where the circuit board 3 is connected to the connector element 1. The connecting region 7 is surrounded by a rim 10 which comprises the groove 9 intended to be filled with a sealing material in a dispensing process. The rim 10 and the groove 9 follow an outline of the connector 5 such that they extend completely circumferentially around the connector 5 in top view on a main extension plane of the rim 10 which is also the connection direction of the connector 5. The groove 9 has four sections 9a, 9b, 9c, 9d forming a rectangular shape in top view along the connection direction, shown in FIG. 4.

In one region of the rim 10, the groove 9 widens to form the dispensing starting region 11 with a conically shaped side wall. In FIG. 5, the funnel-shaped geometry of the groove 9 in the dispensing starting region 11 can be seen. The dispensing starting region 11 is comprised by one of the four sections and is located at a distance from each of the edges of the groove 9.

In order to apply the sealing material, a dispensing needle is inserted into the dispensing starting region 11 from above while the circuit board 3 has already been connected to the connector element 1. Either a robotic arm guides the relatively long needle around the circuit board 3 through the groove 9 or the needle is held in place and the connector element 1 is turned by a robotic arm. Due to the funnel-shaped geometry of the groove 9 in the dispensing starting region 11, the needle can be inserted securely and easily into the groove 9.

1-12. (canceled)

13. A connector element for an electronic component, the connector element comprising:
a connecting region for connecting a circuit board to the connector element;
a connector for connecting the connector element to another component;
a sealing area configured to be brought in contact with a corresponding mating area of a housing, said sealing area including a narrow groove to be filled with a sealing material in a dispensing process, said narrow groove having a depth and a dispensing starting region; and
said dispensing starting region having:
a larger width than said narrow groove, and
a conically shaped side wall defining a conus with a tip pointing towards said depth of said narrow groove.

14. The connector element according to claim 13, wherein said groove extends completely circumferentially around said connector.

15. The connector element according to claim 14, wherein said groove has four sections forming a rectangular shape in top view along a connection direction of said connector.

16. The connector element according to claim 15, wherein one of said four sections includes said dispensing starting region, said rectangular shape has edges, and said dispensing starting region is disposed at a distance from said edges of said rectangular shape.

17. The connector element according to claim 13, wherein said groove has inner and outer sections, said conically shaped side wall is disposed on said inner section of said groove, and said outer section of said groove is evenly formed both in said dispensing starting region and outside of said dispensing starting region.

18. The connector element according to claim 13, wherein said sealing material is an adhesive.

19. The connector element according to claim 13, wherein the connector element is formed of an injection-molded plastic material.

20. An electronic component, comprising:
at least one circuit board;
a housing disposed around said at least one circuit board; and
a connector element according to claim 13.

21. The electronic component according to claim 20, wherein said at least one circuit board protrudes from said connector element over a protruding distance D>5*b, wherein b is a width of said groove.

22. The electronic component according to claim 20, wherein said at least one circuit board protrudes from said connector element over a protruding distance D>10*b, wherein b is a width of said groove.

23. The electronic component according to claim 20, wherein the electronic component is a control unit of a selective catalytic reduction system of a vehicle.

24. A method for assembling an electronic component according to claim 13, the method comprising the following steps:
connecting the circuit board to the connecting region of the connector element;
dispensing the sealing material in the narrow groove starting in the dispensing starting region;
using a needle being substantially parallel to a plane of the circuit board to dispense the sealing material; and
placing a housing around the circuit board while causing a mating region of the housing to contact the sealing region.
